(19) United States
(12) Patent Application Publication
(10) Pub. No.: US 2013/0209310 A1
(43) Pub. Date: Aug. 15, 2013

(54) THERMAL DIFFUSION CONTROL FILM FOR USE IN MAGNETIC RECORDING MEDIUM, FOR HEAT-ASSISTED MAGNETIC RECORDING, MAGNETIC RECORDING MEDIUM, AND SPUTTERING TARGET

(71) Applicant: KABUSHIKI KAISHA KOBE SEIKO SHO (KOBE STEEL, LTD.), (US)

(72) Inventors: Hideo FUJII, Hyogo (JP); Yoko Shida, Hyogo (JP)

(73) Assignee: KABUSHIKI KAISHA KOBE SEIKO SHO (KOBE STEEL, LTD.), Kobe-shi (JP)

(21) Appl. No.: 13/758,104

(22) Filed: Feb. 4, 2013

(30) Foreign Application Priority Data
Feb. 14, 2012 (JP) 2012-029717

(51) Int. Cl. G11B 5/738; C23C 14/34

(52) U.S. Cl. CPC G11B 5/738; C23C 14/3407
USPC 420/507; 204/298.13

(57) ABSTRACT

A thermal diffusion control film which includes an Ag alloy containing Nd, Bi, and Si. The thermal diffusion control film can be used for a magnetic recording medium for heat-assisted magnetic recording. The thermal diffusion control film has a good heat resistance even after heat hysteresis at about 600° C.

### CROSS-REFERENCE TO RELATED APPLICATIONS

This application claims priority from Japanese Patent Application No. 2012-029717 filed on Feb. 14, 2012, the entire subject matter of which is incorporated herein by reference.

### BACKGROUND OF THE INVENTION

1. Technical Field

The present invention relates to an Ag alloy thin film which is useful as a thermal diffusion control film disposed between a substrate and a recording film or an underlying layer in a magnetic recording medium for use in hard disk drives for heat-assisted magnetic recording (HAMR), in which magnetic recording is assisted through local heating with a laser beam or near-field light in a recording process, a magnetic recording medium using the same, and a sputtering target to be used for deposition of the Ag alloy thin film.

2. Background Art

In magnetic recording media, a heat-assisted magnetic recording in which a target area is heated with a laser beam or near-field light only during recording has been proposed. The heat-assisted magnetic recording utilizes the fact that the magnetocrystalline anisotropy of a recording material decreases with an increase of temperature, and is an integrated recording method of a magnetic recording technique and an optical recording technique. According to the heat-assisted magnetic recording, in a high-coercivity medium that cannot be recorded in general magnetic recording, after performing recording by locally decreasing the coercivity of a recording magnetic portion by heat by means of irradiation with a laser beam, the medium is quenched to room temperature to increase the cohesive force during storage.

In the heat-assisted magnetic recording, since laser irradiation is performed during laser writing, it is desirable that, in addition to high thermal conductivity, the medium is rapidly cooled after heating during recording, and the medium is also required to have high thermal diffusivity. Then, in order to promote thermal diffusion, a thermal diffusion control film having high thermal conductivity is disposed between a substrate and an underlying layer or a recording film. FIG. 1 shows an example of a film configuration of a heat-assisted magnetic recording medium including a thermal diffusion control film.

The thermal conductivity and the thermal diffusivity are described below. The thermal conductivity is a quantity expressing a ratio of rate at which thermal energy is conducted when a stationary temperature gradient is present. In contrast, the thermal diffusivity is a quantity expressing a rate at which a temperature distribution is relieved to become a thermally equilibrium state and is expressed according to the following equation.

(Thermal conductivity)=(Thermal diffusivity)×(Specific heat)×(Density)

In the right-hand side of the foregoing equation, the value obtained by multiplying the specific heat by the density corresponds to a specific heat per volume. Since metals have a substantially constant value irrespective of the substance thereof, metals having high thermal conductivity also have high thermal diffusivity. Then, Ag is preferably used as the metal that is high in both the thermal conductivity and the thermal diffusivity.

As compared with Au and Cu, Ag has the higher thermal diffusivity and has favorable thermal properties. Thus, Ag is the most suitable for a thermal diffusion control film.

However, an Ag thin film generally has a high average surface roughness Ra of several nanometers or more and easily undergoes a change in its film structure, such as grain growth and surface roughening, by heating. On the other hand, in the magnetic recording medium, a distance between a magnetic head and a magnetic recording medium is very small, and therefore, the magnetic recording medium is believed to be necessary to have a very smooth surface such that its Ra is about 1.0 nm or less. In addition, in the heat-assisted magnetic recording, the magnetic recording medium is exposed to high-temperature heating exceeding 100° C. and receives repetition of such high-temperature heating and rapid cooling to room temperature, and therefore, the magnetic recording medium is also required to have high heat resistance.

Then, Patent Document 1 regarding an Ag alloy thermal diffusion control film having all of properties of high thermal conductivity, high thermal diffusivity, high surface smoothness, and high heat resistance has been proposed. Patent Document 1 discloses an Ag alloy containing a prescribed amount of each of Nd and/or Y and Bi, and preferably further containing a prescribed amount of Cu.
Patent Document 1: JP-A-2011-108328

### SUMMARY OF THE INVENTION

At the time of filing the above-described Patent Document 1, in the heat-assisted magnetic recording, it was assumed that the heating temperature during recording is approximately from 100 to 300° C., and therefore, in Patent Document 1, the evaluation was performed in the vicinity of the foregoing temperature. Specifically, Patent Document 1 discloses that in Example 1, the average surface roughness Ra after the vacuum heat treatment at 200° C. for 10 minutes can be suppressed to 1.0 nm or less; and that in Example 2, even after performing the heat treatment in the air at 400° C. for one hour, the smooth surface was kept, and the growth of crystal grains to be caused due to the surface diffusion of Ag can be suppressed.

However, in recent years, the heat hysteresis in fabrication of a recording layer (heating temperature during recording) is getting more comprehensive, and it is assumed that the heat hysteresis during forming a recording layer reaches about 600° C. Following this, a level of the heat resistance required for the thermal diffusion control film increases more and more. Accordingly, it is desirable to provide a novel Ag alloy thermal diffusion control film for use in a magnetic recording medium for heat-assisted magnetic recording, which, even after being subjected to such very high heat hysteresis, is able to keep high thermal conductivity and thermal diffusivity and high surface smoothness and has excellent heat resistance.

In view of the foregoing circumstance, the present invention has been made, and an aspect of the present invention is to provide: a novel Ag alloy thermal diffusion control film for use in a magnetic recording medium for heat-assisted magnetic recording, which, even when the heat hysteresis during forming a recording layer is increased to about 600° C. which is higher than that in the related art, has excellent surface smoothness and is able to ensure very excellent heat resistance; a magnetic recording method using the same; and a sputtering target useful for the formation of such an Ag alloy thermal diffusion control film.

The present invention includes the following aspects.

(1) A thermal diffusion control film, comprising an Ag alloy containing Nd, Bi, and Si.

(2) The thermal diffusion control film according to (1), wherein the Ag alloy contains:

Nd: more than 0 atomic % and 1.0 atomic % or less;

Bi: more than 0 atomic % and 0.1 atomic % or less; and

Si: more than 0.05 atomic % and 3 atomic % or less.

The thermal diffusion control film may be a thermal diffusion control film to be used in a magnetic recording medium for heat-assisted magnetic recording. The thermal diffusion control film may consist essentially of the Ag alloy containing Nd, Bi and Si, or may consist of the Ag alloy containing Nd, Bi and Si.

(3) A magnetic recording medium, comprising the thermal diffusion control film according to (1) or (2).

The magnetic recording medium may be a magnetic recording medium for heat-assisted magnetic recording.

(4) A sputtering target, comprising an Ag alloy containing Nd, Bi, and Si.

(5) The sputtering target according to (4), wherein the Ag alloy contains:

Nd: more than 0 atomic % and 1.0 atomic % or less;

Bi: more than 0 atomic % and 0.5 atomic % or less; and

Si: more than 0.05 atomic % and 3 atomic % or less.

The sputtering target may be used for producing the thermal diffusion control film according to (1) or (2). The sputtering target may consist essentially of the Ag alloy containing Nd, Bi, and Si, or may consist of the Ag alloy containing Nd, Bi, and Si.

According to the present invention, the composition of the Ag alloy is appropriately controlled, and therefore, even after high-temperature heat hysteresis at about 600° C., high thermal conductivity and high thermal diffusivity and high surface smoothness can be kept, and extremely excellent heat resistance can be ensured. Accordingly, the thermal diffusion control film according to the present invention is suitably used for a magnetic recording medium for heat-assisted magnetic recording.

### BRIEF DESCRIPTION OF THE DRAWINGS

FIG. 1 is an explanatory view showing an example of a film configuration of a magnetic recording medium for heat-assisted magnetic recording.

### DETAILED DESCRIPTION OF THE INVENTION

In order to provide an Ag alloy capable of ensuring favorable heat resistance even after high-temperature heat hysteresis at about 600° C., the present inventors made investigations on the basis of a ternary alloy of an Ag—Nd—Bi alloy among the Ag alloys described in JP-A-2011-108328. As a result, as shown in the examples as described later, it has become clear that in the Ag—Nd—Bi alloy, when the temperature of the heat hysteresis is increased to about 600° C., the surface smoothness decreases, and the average surface roughness Ra becomes large, and thus, high heat resistance cannot be ensured. Then, as a result of further extensive and intensive investigations, it has been found that when an Ag—Nd—Bi—Si alloy obtained by further adding Si to the foregoing Ag-based ternary alloy (Ag—Nd—Bi alloy) is used, even after high-temperature heat hysteresis at 600° C., favorable surface smoothness can be ensured (the average surface smoothness Ra is low) while keeping high thermal conductivity and thermal diffusivity, leading to accomplishment of the present invention.

Specifically, the thermal diffusion control film according to the present invention includes an Ag—Nd—Bi—Si alloy. The thermal diffusion control film may consist essentially of an Ag—Nd—Bi—Si alloy or may consist of an Ag—Nd—Bi—Si alloy. By using an Ag-based quaternary alloy having the foregoing composition, it is possible to provide a thermal diffusion control film for use in a magnetic recording medium for heat-assisted magnetic recording, which is excellent in thermal conductivity and thermal diffusivity and surface smoothness, not only immediately after deposition but even after high-temperature heat hysteresis at about 600° C.

In the present invention, it is meant by the terms “excellent in heat resistance after high-temperature heat hysteresis” that when heat hysteresis at 650° C. for 10 seconds is applied by the method described in the examples as described later, not only the thermal conductivity is high as 150 W/(m·K) or more (evaluation: A), but the average surface roughness Ra is 2.0 nm or less (evaluation: B), and Ra is preferably 1.0 nm or less (evaluation: A).

In particular, the characteristic portion of the present invention as compared with JP-A-2011-108328 resides in the fact that it is elucidated that Si is an effective element as a heat resistance enhancing element after high-temperature heat hysteresis. The usefulness of Si is hereunder described in detail on the basis of results of the examples as described later.

First of all, Nos. 1 to 5 in Table 1 as described later are concerned with simulated examples of the Ag—Bi—Nd alloy film described in JP-A-2011-108328, and these are concerned with examples of a ternary alloy in which the amount of Nd is changed within the range of from 0.20 to 0.93 atomic % while substantially fixing the amount of Bi (about 0.06 atomic %). In all of these examples, though the thermal conductivity after high-temperature heat hysteresis at 650° C. for 10 seconds was favorable, the average surface smoothness (Ra) decreased. Of these, in No. 5, the Ra after high-temperature heat hysteresis was 2.3 nm, a value of which was the lowest among the foregoing Nos. Nevertheless, this value does not reach the desirable level (Ra≦2.0 nm) and is still high.

In detail, it is found that while the Ra after high-temperature heat hysteresis tends to become low (the surface roughness becomes favorable) with an increase of the Nd amount (No. 1→No. 5), the thermal conductivity after high-temperature heat hysteresis tends to become low. Accordingly, from the viewpoint of realizing only a reduction of the Ra after high-temperature heat hysteresis, it may be considered to more increase the Nd amount of the Ag—Bi—Nd alloy film as compared with that of the foregoing No. 5 (Nd amount=0.93 atomic %). If so, it may be expected that the thermal conductivity after high-temperature heat hysteresis conversely becomes low, and thus, it is impossible to ensure the desired level (150 W/(m·K) or more) of the thermal conductivity. That is, it is found that both an action to suppress the Ra after high-temperature heat hysteresis (merit) and an action to decrease the thermal conductivity after high-temperature heat hysteresis (demerit) are exhibited with an increase of the Nd amount.

Accordingly, it has been found from the results of the foregoing experiments that in order to solve the problems of the present invention, there is a limit with respect to the Ag—Bi—Ni ternary alloy film (the problems of the present invention cannot be solved).

On the other hand, Nos. 9 to 14 in Table 1 are concerned with Ag—Nd—Bi—Si alloy films according to the present invention, in which Si is further added to the Ag—Bi—Nd alloy films of the foregoing Nos. 1 to 5 while making the Bi amount to the same degree. In these Ag—Nd—Bi—Si alloy films, not only the thermal conductivity and Ra immediately after deposition (as-depo.) were favorable (evaluation: A; the details of the evaluation criteria should be referred to the section of the examples as described later), but the thermal conductivity and Ra after high-temperature heat hysteresis at 650° C. for 10 seconds were also favorable (evaluation of thermal conductivity: A, evaluation of Ra: B or A). That is, it has been found that both high thermal conductivity and high surface smoothness (reduction of Ra) after high-temperature heat hysteresis, which can not be accomplished in the foregoing Ag—Bi—Nd alloy films, can be accomplished by the addition of Si.

In details, the effects based on the addition of Si are the same as those of Nd as described above, and it has been found that while the action to reduce the Ra after high-temperature heat hysteresis is effectively exhibited with an increase of the Si amount, the thermal conductivity after high-temperature heat hysteresis decreases. Accordingly, in the Ag—Bi—Nd—Si alloy film according to the present invention, for the purpose of effectively suppressing the Ra after high-temperature heat hysteresis due to Si while keeping the high thermal conductivity after high-temperature heat hysteresis, it is necessary to appropriately control the Si amount in relation with the Nd amount. In comparison with Nos. 9 to 11 in Table 1 which are concerned with examples of the present invention, when the amount of Si added in relation with the Nd amount is decreased as in Nos. 6 to 8, the Ra after high-temperature heat hysteresis became high without sufficiently exhibiting the addition effects based on the addition of Si.

Specifically, a consideration is made on the basis of Table 1.

First of all, when examples of the present invention (Nos. 9 to 11), comparative examples (Nos. 6 to 8), and a conventional example (No. 1) as simulated for Patent Document 1 (no addition of Si), in which the Nd amount (Nd amount=about 0.2 atomic %) and the Bi amount (Bi amount=about 0.05 atomic %) are substantially fixed, were compared with respect to the Ra after high-temperature heat hysteresis, the Ra was low in the order of (conventional example)→(comparative examples)→(examples of the present invention). In detail, in the foregoing examples of the present invention containing from 1.25 to 1.70 atomic % of Si, the Ra was from 0.6 to 0.8 nm (evaluation: A); whereas in the foregoing comparative examples containing only from 0.32 to 0.94 atomic % of Si, in which the Si amount is low as compared with that in the examples of the present invention, the Ra was high as from 2.2 to 3.4 nm (evaluation: C), and in the conventional example not containing Si, the Ra was the highest as 7.3 nm.

In the following Table 1, only the results obtained in the case where the Si amount in the Ag alloy film is 1.70 atomic % (No. 11) at maximum are shown. However, it may be sufficiently expected from the results of the following fundamental experiments that in the Ag—Bi—Nd—Si alloy containing substantially the same amounts of Bi and Nd as those in the foregoing Nos. 9 to 11 which are concerned with examples of the present invention, even when the Si amount is increased to the vicinity of 3 atomic %, the desired effects (keeping high thermal conductivity and high surface smoothness even after high-temperature heat hysteresis) can be ensured. That is, while not described in Table 1, when an Ag alloy film was deposited in the same manner as that described above by using a sputtering target of Ag—Bi (0.35 atomic %)-Nd (0.2 atomic %)-Si (3 atomic %), not only the thermal conductivity after high-temperature heat hysteresis was 181.4 W/(m·K) (evaluation: A), but the Ra after high-temperature heat hysteresis was 0.7 nm (evaluation: A). The composition of the Ag alloy film prepared by using this sputtering target was not measured. However, when consideration is made on the fact that the composition of the foregoing sputtering target and the compositions of the sputtering targets used in Nos. 9 to 11 which are concerned with examples of the present invention are identical in the Bi amount and Nd amount but different only in the Si amount, or a relation between the composition of the sputtering targets in the examples of the present invention and the composition of the Ag alloy film, the composition of the thin film obtained using the foregoing sputtering target is probably substantially identical with the foregoing examples of the present invention with respect to the Bi amount and Nd amount, and it may be assumed that the Si amount is close to about 3 atomic %. Accordingly, it may be believed that in the foregoing Ag—Bi—Nd—Si alloy film, even when the Si amount is increased to the vicinity of 3 atomic %, the desired effects are obtained.

In the foregoing examples, the thermal conductivity after high-temperature heat hysteresis was lower in the order of (conventional example)→(comparative examples)→(examples of the present invention), and in the foregoing examples of the present invention, the lowest thermal conductivity was obtained. However, all of these examples satisfied the acceptability criterion of the present invention (150 W/(m·K) or more), and the desired high thermal conductivity was able to be kept.

Next, when examples of the present invention (Nos. 12 to 14) and a conventional example (No. 5) as simulated for JP-A-2011-108328 (no addition of Si), in which the Nd amount (Nd amount=about 0.9 atomic %) and the Bi amount (Bi amount=about 0.1 atomic %) are substantially fixed, were compared with respect to the Ra after high-temperature heat hysteresis, the Ra was lower in the order of (conventional example)→(examples of the present invention). In detail, in the examples of the present invention containing from 0.09 to 0.29 atomic % of Si, the Ra was from 1.1 to 1.6 nm (evaluation: B); whereas in the conventional example not containing Si, the Ra was high as 2.3 nm.

In the foregoing examples, the thermal conductivity after high-temperature heat hysteresis of the examples of the present invention were lower than that of the conventional example. However, all of the examples of the present invention sufficiently satisfied the acceptability criterion (150 W/(m·K) or more) and the desired high thermal conductivity was able to be kept.

In addition, when Nos. 9 to 11 (Nd amount=about 0.2 atomic %) and Nos. 12 to 14 (Nd amount=about 0.9 atomic %), all of which are concerned with examples of the present invention, were compared, when the Nd amount is high, the Ra after high-temperature heat hysteresis can be controlled low as described previously. In Nos. 12 to 14 in which the Nd amount is higher than that in Nos. 9 to 11, the film could have the desired characteristics at a smaller amount of Si as compared with that in Nos. 9 to 11. Conversely speaking, it is found that in Nos. 9 to 11 in which the Nd amount is smaller than that in Nos. 12 to 14, the film may not be able to have the desired characteristics unless the Si amount is increased as compared with that in Nos. 12 to 14.

It is found from the foregoing results that in the case of Bi≦0.1 atomic % and Nd≦0.3 atomic %, the Si amount may be made at least more than 0.94 atomic % (this can be considered from the results of Nos. 9 to 11 and No. 8).

Actions and effects of the elements (Nd, Bi, and Si) which constitute the film according to the present invention are hereunder described.

Nd is an element contributing to an enhancement of the surface smoothness (reduction of Ra) both immediately after deposition and after high-temperature heat hysteresis. The foregoing effect tends to be enhanced with an increase of the Nd amount. However, when Nd is added in excess, the thermal conductivity tends to decrease both immediately after deposition and after high-temperature heat hysteresis. In particular, it is preferable to appropriately control the Nd amount in relation with the Si amount.

The content of Nd is preferably more than 0 atomic % and 1.0 atomic % or less, more preferably 0.1 atomic % or more and 0.7 atomic % or less, and further more preferably 0.1 atomic % or more and 0.5 atomic % or less.

Similar to Nd, Bi has an action to enhance the surface smoothness. In particular, it may be assumed that its action to reduce the Ra after high-temperature heat hysteresis is larger than that of Nd (the details will be described later). However, when Bi is added in excess, the thermal conductivity decreases, and therefore, it is preferable to appropriately control the Bi amount in relation with the Nd amount and the Si amount.

The content of Bi is preferably more than 0 atomic % or more, and preferably 0.1 atomic % or less, more preferably 0.07 atomic % or less, and further more preferably 0.06 atomic % or less.

As described above, Bi would greatly contribute to the reduction of Ra after high-temperature heat hysteresis as compared with Nd. This may be assumed from the experimental results obtained by using a sputtering target not containing Bi (not shown in Table 1). That is, when Ag alloy films were deposited in the same manner as that described above by using two types of sputtering targets which do not contain Bi and are identical in the Nd amount but different only in the Si amount [(a) a sputtering target of Ag—Nd (0.2 atomic %)-Si (1.4 atomic %) and (b) a sputtering target of Ag—Nd (0.2 atomic %)-Si (3 atomic %)], the thermal conductivity after high-temperature heat hysteresis was 193.6 W/(m·K) (evaluation: A) in the case of (a) and 156.5 W/(m·K) (evaluation: A) in the case of (b), respectively, and the Ra after high-temperature heat hysteresis was 2.5 nm (evaluation: C) in the case of (a) and 2.6 nm (evaluation: C) in the case of (b), respectively. The composition of the Ag alloy film obtained by using each of the sputtering targets (a) and (b) was not measured. However, in the case of not containing Bi in a sputtering target as described above, when consideration is made on the fact that even when the Si amount in the sputtering target was changed within the range of from 1.4 to 3 atomic %, the Ra after high-temperature heat hysteresis was still high, it may be thoroughly assumed that the action of Bi to reduce the Ra after high-temperature heat hysteresis is very large.

Si is an element which is the most unique to the present invention and is an element which is useful for providing both high thermal conductivity after high-temperature heat hysteresis and high surface smoothness after high-temperature heat hysteresis. That is, Si is an element contributing to an enhancement of the surface smoothness (reduction of Ra) both immediately after deposition and after high-temperature heat hysteresis. The foregoing effect tends to be enhanced with an increase of the Si amount. However, when Si is added in excess, the thermal conductivity tends to decrease both immediately after deposition and after high-temperature heat hysteresis. Therefore, in particular, it is preferable to appropriately control the Si amount in relation with the Nd amount such that the desired characteristics are exhibited. In addition, as described later, it is preferable that the Ag alloy film according to the present invention is deposited by the sputtering method using an Ag alloy sputtering target containing the elements which constitute the Ag alloy film. However, when the Si amount increases, there is a concern that breakage of the Ag alloy sputtering target occurs during manufacturing the Ag alloy sputtering target or during sputtering. Thus, it is preferable to appropriately control an upper limit of the Si amount by taking such a viewpoint into consideration.

The content of Si is preferably more than 0.05 atomic % and 3 atomic % or less, more preferably 0.1 atomic % or more and 2.0 atomic % or less, and further more preferably 1.0 atomic % or more and 2.0 atomic % or less.

The Ag alloy film which is used in the present invention contains the foregoing elements with a balance being Ag and inevitable impurities.

As the inevitable impurities which may be inevitably mixed therein during the manufacture of the sputtering target or the like, C (carbon) and 0 (oxygen) are exemplified, and these elements may be contained in an amount of 0.01 atomic % or less, respectively.

The configuration of the Ag alloy film according to the present invention has been described. The foregoing Ag alloy film is to be used as a thermal diffusion control film for use in a magnetic recording medium for heat-assisted magnetic recording, and its film thickness is not particularly limited so far as the film is in general useful for the foregoing applications. In general, the film thickness of the foregoing Ag alloy film falls within the range of from 10 to 270 nm.

The foregoing Ag alloy film is more preferably formed by the sputtering method using a sputtering target (hereinafter also referred to as a “target”). This is because according to the sputtering method, a thin film having excellent in-plane uniformity with respect to components or film thickness can be easily formed as compared with a thin film formed by an ion plating method or electron beam deposition method.

In the formation of the foregoing Ag alloy film by the sputtering method, it is preferable to use an Ag alloy sputtering target containing the above-described elements (Nd, Bi, and Si) as the target.

Nd and Si which are contained in the Ag alloy sputtering target may be controlled in substantially same amounts as those in the Ag alloy film. However, Bi is an element which is liable to be concentrated in the vicinity of the surface of the Ag alloy film, and therefore, it is preferable that the sputtering target contains Bi in an amount of about 5 times the Bi amount in the Ag alloy film.

Specifically, the content of Bi is preferably more than 0 atomic % and 0.5 atomic % or less, and more preferably 0.1 atomic % or more and 0.45 atomic % or less, and further more preferably 0.2 atomic % or more and 0.4 atomic % or less. The content of Nd is preferably more than 0 atomic % and 1.0 atomic % or less, more preferably 0.1 atomic % or more and 0.7 atomic % or less, and further more preferably 0.1 atomic % or more and 0.5 atomic % or less. The content of Si is preferably more than 0.05 atomic % and 3 atomic % or less, more preferably 0.1 atomic % or more and 2.0 atomic % or less, and further more preferably 1.0 atomic % or more and 2.0 atomic or less.

With regard to the shape of the target, any shape (for example, a square plate shape, a circular plate shape, a toroidal plate shape, etc.) depending upon the shape or structure of a sputtering apparatus may be used.

Examples of a manufacturing method of the foregoing target include a melting and casting method, a powder sintering method, and a spray forming method.

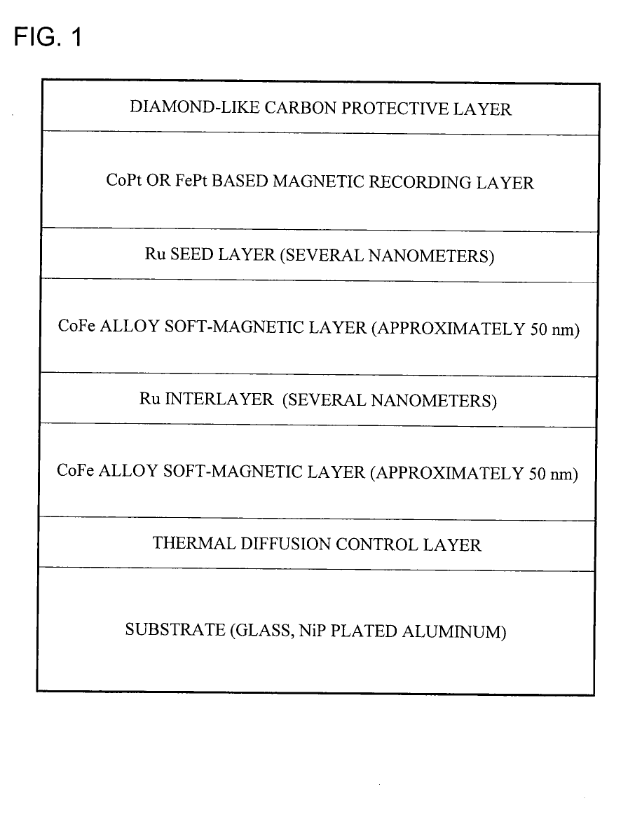

The Ag alloy thermal diffusion control film according to the present invention is suitably used for a magnetic recording medium for heat-assisted magnetic recording. The film configuration of the magnetic recording medium for heat-assisted magnetic recording is not limited so far as it is usually useful. Representatively, the film configuration is a laminated structure including the foregoing thermal diffusion control film, at least one underlying layer, at least one magnetic recording layer, and at least one protective layer, on/above a substrate. The foregoing thermal diffusion control film is, for example, disposed between the substrate and the underlying layer or the magnetic recording layer. FIG. 1 shows an example of a magnetic recording medium for heat-assisted magnetic recording to which the Ag alloy thermal diffusion control film according to the present invention may be adapted. It should not be construed that the present invention is limited thereto.

### EXAMPLES

The present invention is more specifically described below with reference to the following examples, but it should not be construed that the present invention is limited to the following examples. Various modifications may be made to these examples without departing from the gist described above and below. These modifications are also within the technical scope of the present invention.

### Example 1

In the present Example, influences of the composition of an Ag alloy thin film on the thermal conductivity, and surface smoothness (Ra) were examined.

Specifically, a variety of Ag alloy films having a thickness of 100 nm as described in Table 1 were formed on a silicon substrate (substrate size: 6 inches) by using a multi-target sputtering apparatus (SH-200, manufactured by Ulvac, Inc.). A composition of each of used sputtering targets is also described in Table 1.

Sputtering conditions are as follows.

Background pressure: <7.5×10⁻⁷ Torr

Ar gas pressure: 2 mTorr

Deposition power: 10 to 300 W

Substrate temperature: Room temperature (22° C.)

The composition of the deposited Ag alloy film was confirmed by means of a quantitative analysis using an ICP emission spectrometer (ICP emission spectrometer: “ICP-8000 MODEL”, manufactured by Shimadzu Corporation).

By using the thus obtained Ag alloy film, its thermal conductivity and surface smoothness (Ra) were examined in the following manners.

### (Measurement of Thermal Conductivity)

With respect to the thermal conductivity, a sheet resistivity was measured using a four-probe resistivity evaluation apparatus, and an electrical resistivity was calculated according to the following equation (1) and then converted into a thermal conductivity according to the following equation (2) in conformity with the Wiedemann-Franz law.

Electrical resistivity(μΩ·cm)=4.532×(Sheet resistivity)×(Ag alloy film thickness) (1)

Thermal conductivity(W/(m·K))=753/(Electrical resistivity)(μΩ·cm) (2)

Each of a thin film immediately after deposition and a thin film after vacuum heat treatment at 650° C. for 10 seconds was measured and evaluated according to the following criteria. In the present Example, a sample evaluated with a rating “A” with respect to the thermal conductivity both immediately after deposition and after vacuum heat treatment at 650° C. for 10 seconds was determined to be acceptable.

(Evaluation Immediately after Deposition)

A: Thermal conductivity≧60 W/(m·K)

B: Thermal conductivity<60 W/(m·K)

(Evaluation after Vacuum Heat Treatment at 650° C. For 10 Seconds)

A: Thermal conductivity≧150 W/(m·K)

B: Thermal conductivity<150 W/(m·K)

In the present Example, though the thermal diffusivity was not measured, a material having high thermal conductivity also has high thermal diffusivity as described previously. The thermal diffusivity was here indirectly evaluated by measuring the thermal conductivity as simply calculated from the sheet resistivity as described above.

### (Measurement of Average Surface Roughness Ra)

Ra was calculated from a measured value in an area of 3 μm×3 μm using an atomic force microscope (AFM). Each of a thin film immediately after deposition and a thin film after vacuum heat treatment at 650° C. for 10 seconds was measured and evaluated according to the following criteria. In the present Example, a sample evaluated with a rating “A” with respect to the Ra immediately after deposition and evaluated with a rating “B” or “A” after vacuum heat treatment at 650° C. for 10 seconds was determined to be acceptable.

(Evaluation Immediately after Deposition)

A: Ra≦1.0 nm

B: Ra>1.0 nm

(Evaluation after Vacuum Heat Treatment at 650° C. For 10 Seconds)

A: Ra≦1.0 nm

B: Ra: >1.0 nm and 2.0 nm

C: Ra>2.0 nm

### (Vacuum Heat Treatment)

A sample was subjected to vacuum evacuation to 2.5×10⁻² Pa by using an RTP furnace (ULVAC RT-6) and then subjected to vacuum heat treatment to 650° C. at an average temperature elevation rate of 1° C./sec, followed by keeping at 650° C. for 10 seconds. Thereafter, the sample was cooled at an average cooling rate of 1° C./sec, and when the temperature reached 100° C. or less, the sample was taken out.

These results are also described in Table 1.

TABLE 1

| | | Composition of film | | | | | | | | | | |
|---|---|---|---|---|---|---|---|---|---|---|---|---|
| | | (balance: Ag and | | | Thermal conductivity (W/(m · K)) | | | | Ra (nm) | | | |
| | | inevitable impurities) | | | | | After | | | | After | |
| | | Bi | Nd | Si | as- | | vacuum | | as- | | vacuum | |
| | Composition of | (atomic | (atomic | (atomic | depos- | Evalua- | heat | Evalua- | depos- | Evalua- | heat | Evalua- |
| No | sputtering target | %) | %) | %) | ited | tion | treatment | tion | ited | tion | treatment | tion |
| 1 | Ag—0.35Bi—0.2Nd | 0.07 | 0.20 | — | 179.0 | A | 288.5 | A | 0.65 | A | 7.3 | C |
| 2 | Ag—0.35Bi—0.34Nd | 0.07 | 0.34 | — | 204.8 | A | 268.9 | A | 0.59 | A | 7.1 | C |
| 3 | Ag—0.35Bi—0.49Nd | 0.06 | 0.49 | — | 147.2 | A | 223.7 | A | 0.58 | A | 7.2 | C |
| 4 | Ag—0.35Bi—0.64Nd | 0.06 | 0.69 | — | 131.4 | A | 201.0 | A | 0.54 | A | 5.0 | C |
| 5 | Ag—0.35Bi—0.93Nd | 0.05 | 0.93 | — | 88.1 | A | 170.5 | A | 0.60 | A | 2.3 | C |
| 6 | Ag—0.35Bi—0.2Nd—0.26Si | 0.07 | 0.25 | 0.32 | 154.6 | A | 252.5 | A | 0.57 | A | 3.4 | C |
| 7 | Ag—0.35Bi—0.2Nd—0.53Si | 0.06 | 0.25 | 0.70 | 130.9 | A | 242.5 | A | 0.63 | A | 3.1 | C |
| 8 | Ag—0.35Bi—0.2Nd—0.79Si | 0.05 | 0.24 | 0.94 | 105.1 | A | 236.7 | A | 0.44 | A | 2.2 | C |
| 9 | Ag—0.35Bi—0.2Nd—1.32Si | 0.03 | 0.24 | 1.25 | 82.5 | A | 199.7 | A | 0.30 | A | 0.7 | A |
| 10 | Ag—0.35Bi—0.2Nd—1.42Si | 0.03 | 0.24 | 1.43 | 75.3 | A | 207.4 | A | 0.50 | A | 0.8 | A |
| 11 | Ag—0.35Bi—0.2Nd—1.72Si | 0.02 | 0.23 | 1.70 | 69.8 | A | 200.4 | A | 0.50 | A | 0.6 | A |
| 12 | Ag—0.35Bi—0.93Nd—0.07Si | 0.06 | 0.93 | 0.09 | 73.3 | A | 186.0 | A | 0.54 | A | 1.6 | B |
| 13 | Ag—0.35Bi—0.93Nd—0.16Si | 0.06 | 0.93 | 0.19 | 71.0 | A | 182.0 | A | 0.54 | A | 1.5 | B |
| 14 | Ag—0.35Bi—0.93Nd—0.25Si | 0.06 | 0.93 | 0.29 | 69.1 | A | 177.7 | A | 0.53 | A | 1.1 | B |

As is clear from Table 1, in Nos. 9 to 14 (examples of the present invention), each of which contains Nd, Bi, and Si with the appropriately controlled amount, high thermal conductivity and favorable surface smoothness were exhibited not only immediately after deposition but after high-temperature heat hysteresis. In addition, it can also be confirmed from these results that the foregoing examples have high thermal diffusivity. On the other hand, in Nos. 1 to 5 as simulated for Patent Document 1, each of which does not contain Si, and Nos. 6 to 8, each of which contains Nd, Bi, and Si but in which the Si amount is not appropriately controlled in relation with the Nd amount, the surface smoothness after high-temperature heat hysteresis decreased.

What is claimed is:

1. A thermal diffusion control film, comprising an Ag alloy containing Nd, Bi, and Si.

2. The thermal diffusion control film according to claim 1, wherein the Ag alloy contains:
Nd: more than 0 atomic % and 1.0 atomic % or less;
Bi: more than 0 atomic % and 0.1 atomic % or less; and
Si: more than 0.05 atomic % and 3 atomic % or less.

3. A magnetic recording medium, comprising the thermal diffusion control film according to claim 1.

4. A magnetic recording medium, comprising the thermal diffusion control film according to claim 2.

5. A sputtering target, comprising an Ag alloy containing Nd, Bi, and Si.

6. The sputtering target according to claim 5, wherein the Ag alloy contains:
Nd: more than 0 atomic % and 1.0 atomic % or less;
Bi: more than 0 atomic % and 0.5 atomic % or less; and
Si: more than 0.05 atomic % and 3 atomic % or less.
